(19) United States
(12) Patent Application Publication
(10) Pub. No.: US 2015/0192605 A1
(43) Pub. Date: Jul. 9, 2015

(54) FIXING DEVICE FOR PROBE

(71) Applicant: HON HAI PRECISION INDUSTRY CO., LTD., New Taipei (TW)

(72) Inventors: BU-SHENG HSU, New Taipei (TW); CHUN-YUAN TIEN, New Taipei (TW); CHIA-MING YEH, New Taipei (TW)

(73) Assignee: HON HAI PRECISION INDUSTRY CO., LTD., New Taipei (TW)

(21) Appl. No.: 14/192,889

(22) Filed: Feb. 28, 2014

(30) Foreign Application Priority Data
Jan. 8, 2014 (TW) 103100602

(51) Int. Cl. G01R 1/04

(52) U.S. Cl. CPC G01R 1/04

(57) ABSTRACT

A fixing device includes a clamping portion and a plurality of suction cups mounted on a bottom surface of the clamping portion. The clamping portion defines a through hole extending through a top surface and the bottom surface of the clamping portion. A plurality of clamping pieces extends from an inner surface bounding the through hole toward the axis of the through hole to clamp the probe extending through the through hole. The suction cups are arranged around the through hole.

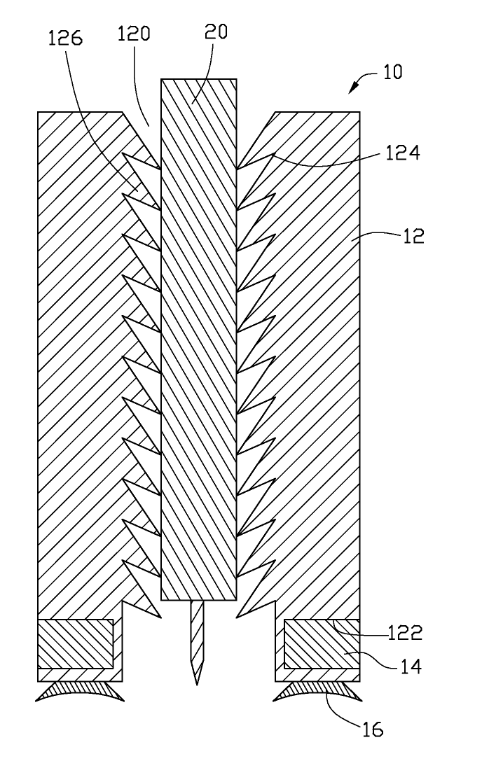

### BACKGROUND

1. Technical Field

The present disclosure relates to a device for fixing a probe.

2. Description of Related Art

An oscillograph is often used for testing circuit boards of electronic devices. However, probes of an oscillograph are generally connected to the oscillograph via cables that are too flexible to stay in place when contacting with the circuit board. As a result, the probes must be held in place manually, which is inconvenient.

### BRIEF DESCRIPTION OF THE DRAWINGS

Many aspects of the present embodiments can be better understood with reference to the following drawing. The components in the drawing are not necessarily drawn to scale, the emphasis instead being placed upon clearly illustrating the principles of the present embodiments. Moreover, in the drawing, the view is schematic.

The FIGURE is a cross-sectional view of an exemplary embodiment of a fixing device, together with a probe.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

The FIGURE shows an embodiment of a fixing device 10. In the embodiment, the fixing device 10 is to fix a probe 20.

The fixing device 10 includes a cylindrical and hollow clamping portion 12, an annular sub-positioning portion 14, and a plurality of suction cups 16 mounted to a bottom surface of the clamping portion 12.

The clamping portion 12 defines a cylindrical through hole 120 extending through a top surface and the bottom surface of the clamping portion 12. A lower portion of an outside circumference of the clamping portion 12 defines an annular slot 122 to receive the sub-positioning portion 14. The suction cups 16 are arranged around the through hole 120. A plurality of clamping pieces 126 slantingly extend downward and toward the axis of the through hole 120 from an inner surface 124 bounding the through hole 120. The clamping portion 12 and the clamping pieces 126 are made of rubber.

In this embodiment, the sub-positioning portion 14 is a weight.

In use, the probe 20 is extended through the through hole 120 from top to bottom and is clamped by the clamping pieces 126. Because the clamping pieces 126 are slantingly downward, the probe 20 will not unwontedly removed from the through hole 120. The suction cups 16 are fixed to a surface to fix the fixing device 10.

In another embodiment, the sub-positioning portion 14 is a magnet, to help to position the fixing device 10 to a metal surface.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fixing device for fixing a probe, comprising:
a clamping portion defining a cylindrical fixing hole extending through a top surface and a bottom surface of the clamping portion; a plurality of clamping pieces extending toward the axis of the through hole, to clamp the probe extend through the through hole; and
a plurality of suction cups mounted to a bottom surface of the clamping portion and around the through hole.

2. The fixing device of claim 1, wherein the clamping portion and the clamping pieces are made of rubber.

3. The fixing device of claim 1, further comprising a sub-positioning portion mounted to a lower portion of the clamping portion.

4. The fixing device of claim 3, wherein the sub-positioning portion is a weight.

5. The fixing device of claim 3, wherein the sub-positioning portion is a magnet.

6. The fixing device of claim 3, wherein the sub-positioning portion is annular, the lower portion of an outside circumference of the clamping portion defines an annular slot to receive the sub-positioning portion.

7. The fixing device of claim 1, wherein the clamping pieces slantingly extends downward and toward the axis of the through hole.
